(19) United States
(12) Patent Application Publication
(10) Pub. No.: US 2021/0104812 A1
(43) Pub. Date: Apr. 8, 2021

(54) SYSTEMS AND METHODS FOR ANTENNA PACKAGING FOR A WIRELESS ACCESS POINT

(71) Applicant: General Electric Company, Schenectady, NY (US)

(72) Inventors: Christopher James Kapusta, Delanson, NY (US); Joseph Alfred Iannotti, Glenville, NY (US); Stanton Earl Weaver, Broadalbin, NY (US); Glen Peter Koste, Niskayuna, NY (US)

(21) Appl. No.: 16/713,488

(22) Filed: Dec. 13, 2019

Related U.S. Application Data
(60) Provisional application No. 62/909,820, filed on Oct. 3, 2019.

(51) Int. Cl. H01Q 1/24; H01Q 21/06; H01L 23/66; G02B 6/42; H01L 23/538; H01L 25/16; H01L 23/15; H01L 23/498; H01L 33/62; H01L 21/48; G02B 6/43

(52) U.S. Cl. CPC H01Q 1/246; H01L 2223/6694; H01L 23/66; G02B 6/4203; H01L 23/5389; H01L 25/167; H01L 23/15; H01L 23/5383; H01L 23/49866; H01L 23/5386; H01L 33/62; H01L 21/4857; G02B 6/428; G02B 6/4279; G02B 6/43; H01L 2223/6677; H01Q 21/065

(57) ABSTRACT

A wireless access point is disclosed. The wireless access point includes a substrate, an antenna structure disposed on the substrate and configured to transmit and receive wireless electromagnetic communication signals, and a fiber-optic interface disposed on the substrate and communicatively coupled to the antenna structure and a fiber-optic cable. The fiber-optic interface is configured to transmit and receive optical communication signals through the fiber-optic cable.

### CROSS-REFERENCE TO RELATED APPLICATIONS

This application claims priority to U.S. Provisional Patent Application Ser. No. 62/909,820 filed Oct. 3, 2019, entitled “SYSTEMS AND METHODS FOR ANTENNA PACKAGING FOR A WIRELESS ACCESS POINT,” which is hereby incorporated by reference in its entirety.

### BACKGROUND

The field of the invention relates generally to antenna packaging, and more particularly, to an antenna package for a wireless access point.

Applications of millimeter band RF communications are increasingly common due to the proliferation of 5G cellular network technology. By using higher frequency signals, some 5G cellular networks are able to achieve higher rates of data transfer. Such networks generally have wireless access points that enable millimeter band wireless communication between the network and 5G-equipped devices (e.g., mobile phones and/or other wireless devices). However, by using higher frequency signals (e.g., millimeter band signals), such wireless access points generally have a shorter range and a reduced ability to communicate through obstructions such as walls. In addition, because 5G wireless access points experience extremely high data rates, such wireless access points generally must maintain a high quality of service in transferring data between a millimeter wave wireless network associated with the wireless access point and a backhaul network. Additionally, at least some currently used technology such as coaxial cables are relatively inefficient and lossy at frequencies associated with such millimeter waves (e.g., frequencies in excess of 20 gigahertz). Further, such millimeter band circuitry requires packaging that is reliable, easy to manufacture and reproduce, and resistant to environmental changes. An improved electronics package for antennas in wireless access points is therefore desirable.

### BRIEF DESCRIPTION

In one aspect, a wireless access point is disclosed. The wireless access point includes a substrate, an antenna structure disposed on the substrate and configured to transmit and receive wireless electromagnetic communication signals, and a fiber-optic interface disposed on the substrate and communicatively coupled to the antenna structure and a fiber-optic cable. The fiber-optic interface is configured to transmit and receive optical communication signals through the fiber-optic cable.

In another aspect, a wireless communication system is disclosed. The wireless communication system includes a network access point communicatively coupled to a communication network, a plurality of fiber-optic cables communicatively coupled to the network access point, and a plurality of wireless access points. Each wireless access point includes a substrate, an antenna structure disposed on the substrate and configured to transmit and receive wireless electromagnetic communication signals, and a fiber-optic interface disposed on the substrate and communicatively coupled to the antenna structure and at least one fiber-optic cable of the plurality of fiber-optic cables. The fiber-optic interface is configured to transmit a first optical communication signal to the network access point and receive a second optical communication signal from the network access point through the fiber-optic cable.

In another aspect, method of manufacturing a wireless access point is disclosed. The method includes forming an antenna structure on a substrate, the antenna structure configured to transmit and receive wireless electromagnetic communication signals, and forming a fiber-optic interface on the substrate, the fiber-optic interface communicatively coupled to the antenna structure and a fiber-optic cable, wherein the fiber-optic interface is configured to transmit and receive optical communication signals through the fiber-optic cable.

### DRAWINGS

These and other features, aspects, and advantages of the present disclosure will become better understood when the following detailed description is read with reference to the accompanying drawings in which like characters represent like parts throughout the drawings, wherein:

FIG. 1 depicts a schematic diagram of an exemplary wireless access point.

FIG. 2 depicts a cross-sectional view of an antenna structure that may be used with the wireless access point illustrated in FIG. 1.

FIG. 3 depicts a cross-sectional view of a fiber-optic interface that may be used with the wireless access point illustrated in FIG. 1.

FIG. 4 depicts a cross-sectional view of another fiber-optic interface that may be used with the wireless access point illustrated in FIG. 1.

FIG. 5 depicts a cross-sectional view of another fiber-optic interface that may be used with the wireless access point illustrated in FIG. 1.

FIG. 6 depicts a cross-sectional view of another exemplary wireless access point.

FIG. 7 depicts a cross-sectional view of another fiber-optic interface that may be used with the wireless access point illustrated in FIG. 1.

FIG. 8 depicts a cross-sectional view of another fiber-optic interface that may be used with the wireless access point illustrated in FIG. 1.

FIG. 9 depicts a cross-sectional view of another fiber-optic interface that may be used with the wireless access point illustrated in FIG. 1.

FIG. 10 depicts a cross-sectional view of another fiber-optic interface that may be used with the wireless access point illustrated in FIG. 1.

FIG. 11 depicts a schematic diagram of another exemplary wireless access point.

FIG. 12 depicts an exemplary wireless communication system that includes the wireless access point illustrated in FIG. 1.

FIG. 13 depicts an exemplary method for manufacturing a wireless access point such as the wireless access point illustrated in FIG. 1.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

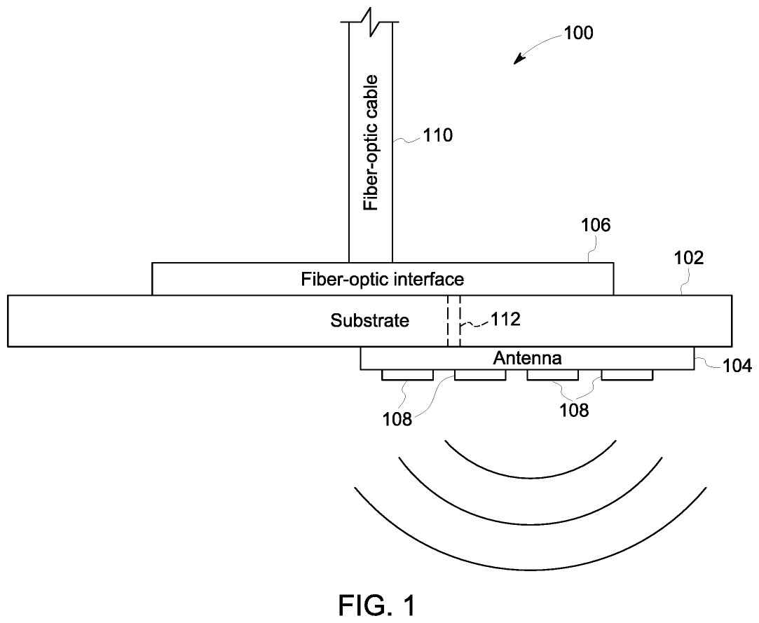

FIG. 1 depicts a schematic diagram of an exemplary wireless access point 100. Wireless access point 100 includes a substrate 102, an antenna structure 104, and a fiber-optic interface 106. In some embodiments, wireless access point 100 is used to implement a wireless communication network such as, for example, a 5G network. Additionally or alternatively, wireless access point 100 may be used as a general optical to radio frequency (RF) communication interface in other application settings.

Substrate 102 is a structure on which antenna structure 104, fiber-optic interface 106, and/or other components of wireless access point 100 are disposed. In some example embodiments, antenna structure 104 and fiber-optic interface 106 include conductive traces that are printed, deposited, sputtered, or otherwise applied to one or more surfaces of substrate 102. Additionally or alternatively, in some example embodiments, antenna structure 104 and fiber-optic interface 106 include surface mount technology (SMT), one or more semiconductor dies, and/or other electronic components attached to substrate 102. For example, antenna structure 104 and fiber-optic interface 106 may include electronic components soldered or stud bump attached to substrate 102. In some embodiments, substrate 102 may include a plurality of layers. In some such embodiments, antenna structure 104 and fiber-optic interface 106 include, for example, conductive traces deposited on one or more surfaces of the plurality of layers and/or vias extending through one or more of the plurality of layers. While antenna structure 104 and fiber-optic interface 106 are depicted as disposed on opposite surfaces of substrate 102 in the exemplary embodiment of FIG. 1, in other exemplary embodiments, antenna structure 104 and fiber-optic interface 106 may be, for example, entirely or partially disposed on a same surface of substrate 102, entirely or partially disposed on different surfaces of substrate 102, entirely or partially disposed in an interior of substrate 102, and/or any combination thereof.

In some embodiments, substrate 102 is transparent. For example, substrate 102 may include a glass material such as, for example, a silicate glass. Substrate 102 being transparent enables wireless access point 100 to be integrated into various applications where reduced interference with light is desirable. For example, wireless access point may be integrated into a light emitting diode (LED) lamp or other light fixture, a window, a display screen, and/or other devices and fixtures.

Antenna structure 104 is disposed on substrate 102 and is configured to transmit and receive a wireless electromagnetic communication signal. For example, antenna structure 104 may be configured to transmit and receive millimeter band signals for 5G communication. In some embodiments, antenna structure 104 may include one or more patch antennas 108. In some embodiments, antenna structure 104 includes a plurality of patch antennas 108 that form an antenna array. In such embodiments, the phases of patch antennas 108 may be controlled to enable directional transmission and reception of wireless signals. In some embodiments, antenna structure includes multiple arrays of patch antennas 108. Additionally or alternatively, a plurality of antenna structures 104 may be disposed on substrate 102, each of the antenna structures 104 including one or more patch antenna 108. In some embodiments, antenna structure 104 includes conductive traces disposed on one or more surfaces of substrate 102. In some such embodiments, the conductive traces are a transparent material such as, for example, thin film indium tin oxide (ITO). As described above with respect to substrate 102, antenna structure 104 being transparent enables wireless access point 100 to be integrated into various applications where reduced interference with light is desirable.

Fiber-optic interface 106 is disposed on substrate 102 and is configured to transmit and receive an optical communication signal through a fiber-optic cable 110. For example, fiber-optic interface 106 may include one or more LEDs and/or laser diodes for converting electrical signals to optical signals and transmitting optical signals, and/or one or more photodiodes and/or photonic integrated circuits (PICs) for receiving optical signals and converting optical signals to electrical signals, such as, for example, RF signals. For example, fiber optical interface may be configured to communicate with one or more external devices using a bidirectional analog optical link. In some embodiments, the optical link uses a code-division multiple access (CDMA) and/or a wavelength-division multiple access (WDMA) channel access method. In some example embodiments, fiber-optic interface 106 may be configured to communicate with a router via fiber-optic cable 110 to enable wireless access point 100 to serve as a cell for a 5G network. In some embodiments, fiber-optic interface 106 includes an RF system on a chip (RF SoC) that is configured to perform at least some functionality of fiber-optic interface 106, such as, for example, RF signal processing. In some embodiments, fiber-optic interface 106 is powered by a DC power supply (not shown). Additionally or alternatively, fiber-optic interface may be at least partially powered using photonic power.

Fiber-optic interface 106 is communicatively coupled with antenna structure 104 via an interconnect 112. While interconnect 112 is shown as a via in the example embodiment of FIG. 1, in other example embodiments, interconnect 112 may be any combination of conductive traces, vias, wires, and/or other connecters capable of transmitting an electronic communication signal. In some embodiments, fiber-optic interface 106 includes conductive traces disposed on one or more surfaces of substrate 102. In some such embodiments, the conductive traces are a transparent material such as, for example, thin film indium tin oxide (ITO). As described above with respect to substrate 102, fiber-optic interface 106 being transparent enables wireless access point 100 to be integrated into various applications where a reduced interference with light is desirable.

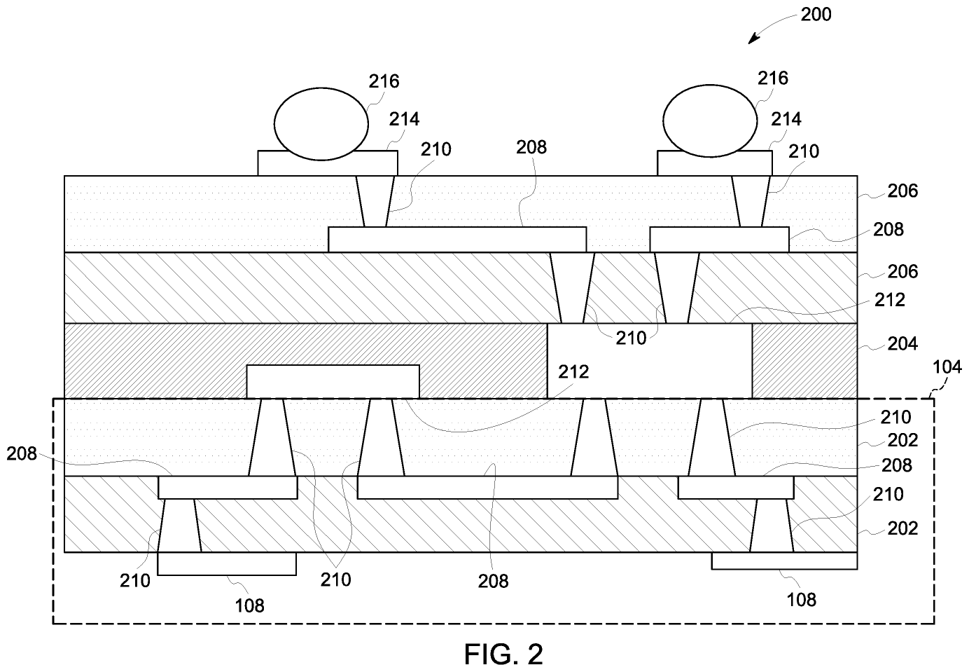

FIG. 2 depicts a cross-sectional view of an exemplary antenna package 200 that may be used with wireless access point 100 shown in FIG. 1. Antenna package 200 includes one or more antenna substrates 202, a core substrate 204, and one or more overlay substrates 206. Antenna package 200 further includes conductive traces 208 and vias 210 that together form electric circuitry within antenna package 200. Conductive traces 208 may be formed on antenna substrates 202, core substrate 204, and/or overlay substrates 206 using, for example, a printing, depositing, sputtering, and/or other application process. Accordingly, antenna package 200 is thus durable and relatively easy to manufacture and reproduce.

In some embodiments, one or more of antenna substrates 202, core substrate 204, overlay substrates 206, conductive traces 208, and vias 210 include and/or are formed from a transparent material. For example, antenna substrates 202, core substrate 204, and/or overlay substrates 206 may include a glass material, and conductive traces 208 and/or vias 210 may include ITO. Antenna package 200 being fully or partially transparent enables antenna package 200 to be integrated into various applications where a reduced interference with light is desirable, such as those described above with respect to wireless access point 100 shown in FIG. 1.

In some embodiments, antenna substrates 202, and conductive traces 208 and vias 210 disposed on antenna substrates 202, form antenna structure 104. In such embodiments, patch antennas 108 are formed on a surface of one of the antenna substrates 202. Conductive traces 208 and vias 210 disposed on antenna substrates 202 form a RF electronic interconnect between patch antennas 108 and other parts of antenna package 200. In some embodiments, conductive traces 208 and vias 210 disposed on antenna substrates 202 form additional RF circuitry, such as transformers, filters, and/or other passive RF circuits.

In some embodiments, core components 212 are disposed within core substrate 204 and may include, for example, semiconductor dies, microelectromechanical systems (MEMS) devices, and/or other electronic components.

In some embodiments, overlay substrates 206 and conductive traces 208 and vias 210 disposed on overlay substrates 206 may form power overlay circuitry that, for example, provides an electrical power and/or logic connection to core components 212 and RF interconnection between antenna structure 104 and circuits external to antenna package 200. In some embodiments, interconnect pads 214 are disposed on a surface of one of the overlay substrates 206 to provide an electrical interconnect between antenna package 200 and other electronic circuits. In the example embodiment, solder balls 216 are disposed on interconnect pads 214 to provide an electrical interconnect. In other embodiments, alternative electrical interconnects may be used, such as wirebond interconnects and/or other interconnects.

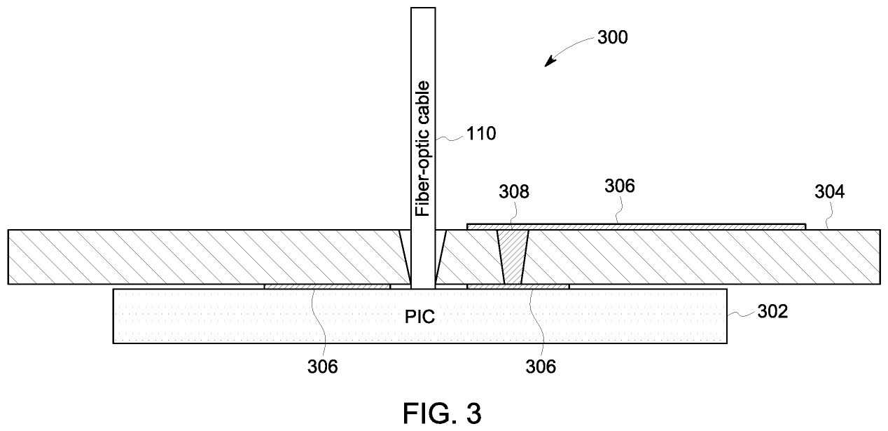

FIG. 3 depicts a cross-sectional view of an exemplary fiber-optic interface 300 that may be used with wireless access point 100 shown in FIG. 1. Fiber-optic interface 300 includes a PIC 302 and a fiber-optic interface substrate 304. In some embodiments, fiber-optic interface substrate 304 is a transparent substrate, for example, a 100 micrometer glass substrate. Fiber-optic interface 300 further includes conductive traces 306 and vias 308 that together form electric circuitry within fiber-optic interface 300. Conductive traces 306 may be formed on fiber-optic interface substrate 304 using, for example, a printing, depositing, sputtering, and/or other application process. Accordingly, fiber-optic interface 300 is thus durable and relatively easy to manufacture and reproduce.

PIC 302 is communicatively coupled to fiber-optic cable 110 and is configured to transmit and receive optical communication signals at fiber-optic cable 110, for example, as a bidirectional analog optical link. In some embodiments, PIC 302 is further configured to convert optical communication signals received at fiber-optic cable 110 to electrical signals, and to convert electrical signals to optical communication signals to transmit via fiber-optic cable 110. In some embodiments, PIC 302 is configured to transfer data via fiber-optic cable 110 over multiple channels using, for example, CDMA and/or WMDA. In some embodiments, PIC 302 may attached to fiber-optic interface substrate 304 via vertical coupling and/or edge coupling, and/or disposed within void formed in fiber-optic interface substrate 304. In some embodiments, PIC 302 may include photodiodes for receiving optical signals. Additionally or alternatively, such photodiodes may be attached to fiber-optic interface substrate via vertical coupling or edge coupling.

In some embodiments, one or more of PIC 302, fiber-optic interface substrate 304, conductive traces 306, and vias 308 include and/or are formed from a transparent material. For example, PIC 302, conductive traces 306, and vias 308 may include ITO. Fiber-optic interface 300 being fully or partially transparent enables fiber-optic interface 300 to be integrated into various applications where a reduced interference with light is desirable, such as those described above with respect to wireless access point 100 shown in FIG. 1.

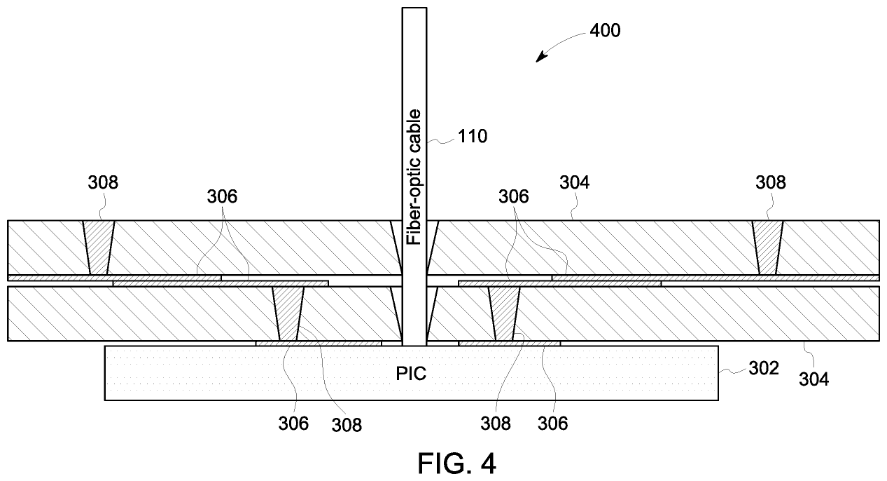

FIG. 4 depicts a cross-sectional view of an exemplary fiber-optic interface 400 that may be used with wireless access point 100 shown in FIG. 1. Fiber-optic interface 400 includes PIC 302, fiber-optic interface substrate 304, conductive traces 306, and vias 308, which generally function as described with respect to FIG. 3. While fiber-optic interface 400 is illustrated as including two fiber-optic interface substrates 304, in alternative embodiments, fiber-optic interface 400 may include additional fiber-optic interface substrates 304. Including a plurality of fiber-optic interface substrates 304 enables more degrees of freedom in configuring fiber-optic interface 400, for example, to optimize optical and electrical parameters of fiber-optic interface 400.

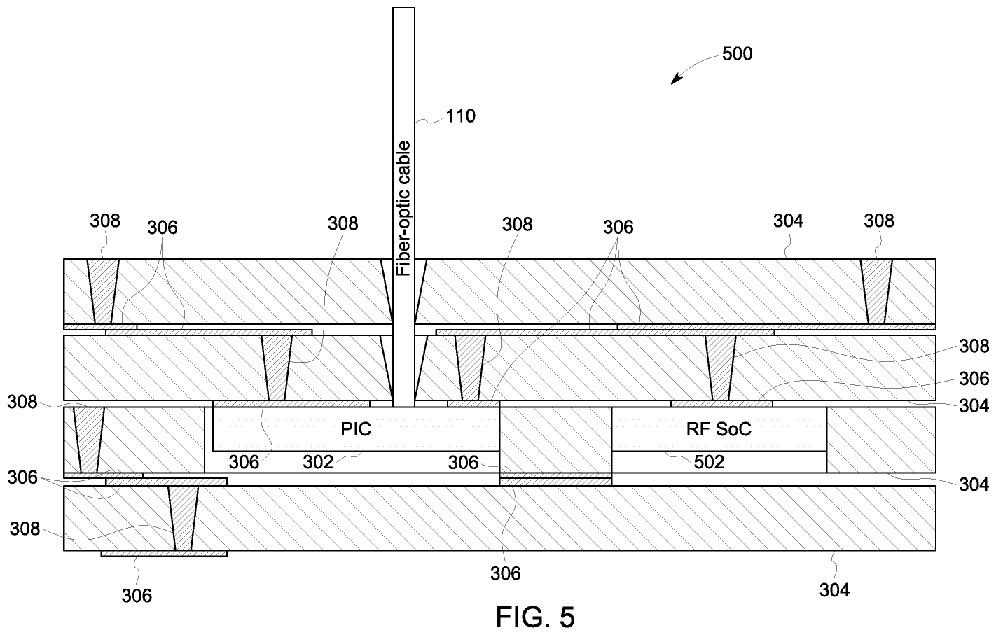

FIG. 5 depicts a cross-sectional view of an exemplary fiber-optic interface 500 that may be used with wireless access point 100 shown in FIG. 1. Fiber-optic interface 500 includes PIC 302, fiber-optic interface substrate 304, conductive traces 306, and vias 308, which generally function as described with respect to FIG. 3. Fiber-optic interface 500 further includes an RF SoC 502. In some embodiments, RF SoC 502 performs RF signal processing functions, such as, for example, encoding, decoding, multiplexing, and/or demultiplexing electrical communication signals received at PIC 302 and/or antenna structure 104 (shown in FIG. 1). In some embodiments, RF SoC 502 includes and/or is formed from a transparent material. For example, RF SoC 502 may include ITO. Fiber-optic interface 500 being fully or partially transparent enables fiber-optic interface 500 to be integrated into various applications where a reduced interference with light is desirable, such as those described above with respect to wireless access point 100 shown in FIG. 1.

In the exemplary embodiment, PIC 302 and RF SoC 502 are embedded within a fiber-optic interface substrate 304. While FIG. 5 depicts PIC 302 and RF SoC 502 as embedded within a single fiber-optic interface substrate 304, in other embodiments, PIC 302 and RF SoC 502 may be completely or partially embedded within a plurality of fiber-optic interface substrates 304 and/or disposed on a surface of one or more fiber-optic interface substrates 304. In some embodiments, the fiber-optic interface substrate 304 in which PIC 302 and/or RF SoC 502 are embedded includes an optical bench that enables optical communication between components disposed on and/or embedded within the optical bench.

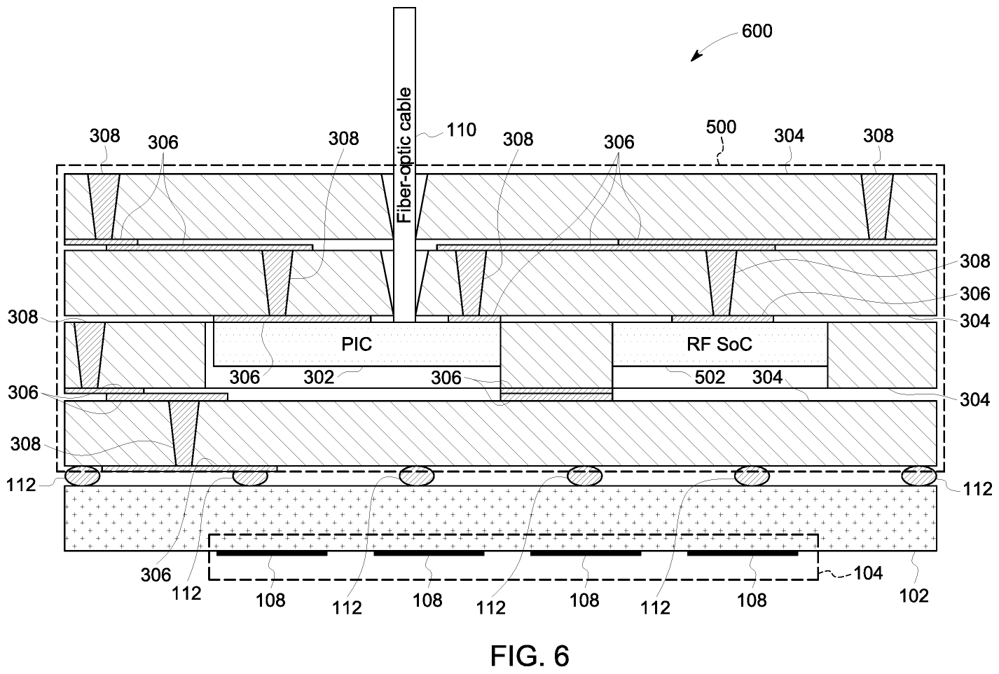

FIG. 6 depicts a cross-sectional view of an exemplary wireless access point 600. Wireless access point 600 includes fiber-optic interface 500, substrate 102, antenna structure 104, and interconnects 112. Substrate 102, antenna structure 104, patch antennas 108, interconnects 112, PIC 302, fiber-optic interface substrate 304, conductive traces 306, vias 308, and RF SoC 502 generally function as described with respect to FIGS. 1, 3, and 5.

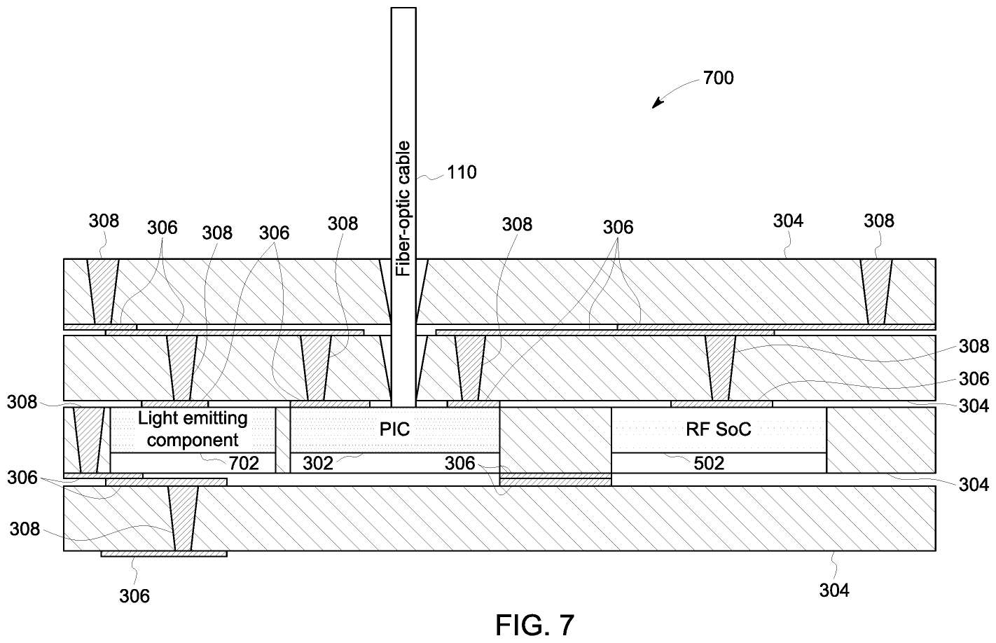

FIG. 7 depicts a cross-sectional view of an exemplary fiber-optic interface 700. Fiber-optic interface 700 includes PIC 302, fiber-optic interface substrate 304, conductive traces 306, vias 308, and RF SoC 502, which generally function as described with respect to FIGS. 3 and 5. Fiber-optic interface 700 further includes a light emitting component 702. Light emitting component 702 includes an active die configured to emit light in response to electrical signals, for example, to transmit via fiber-optic cable 110. For example, light emitting component 702 may include an active die that includes a vertical cavity surface emitting laser (VCSEL), light emitting diode (LED), edge emitting laser, superluminescent LED (SLED), and/or another light emitting device. In the exemplary embodiment, light emitting component 702 is embedded within a fiber-optic interface substrate 304. While FIG. 7 depicts light emitting component 702 as embedded within a single fiber-optic interface substrate 304, in other embodiments, light emitting component 702 may be completely or partially embedded within a plurality of fiber-optic interface substrates 304 and/or disposed on a surface of one or more fiber-optic interface substrates 304, for example, via vertical coupling and/or edge coupling.

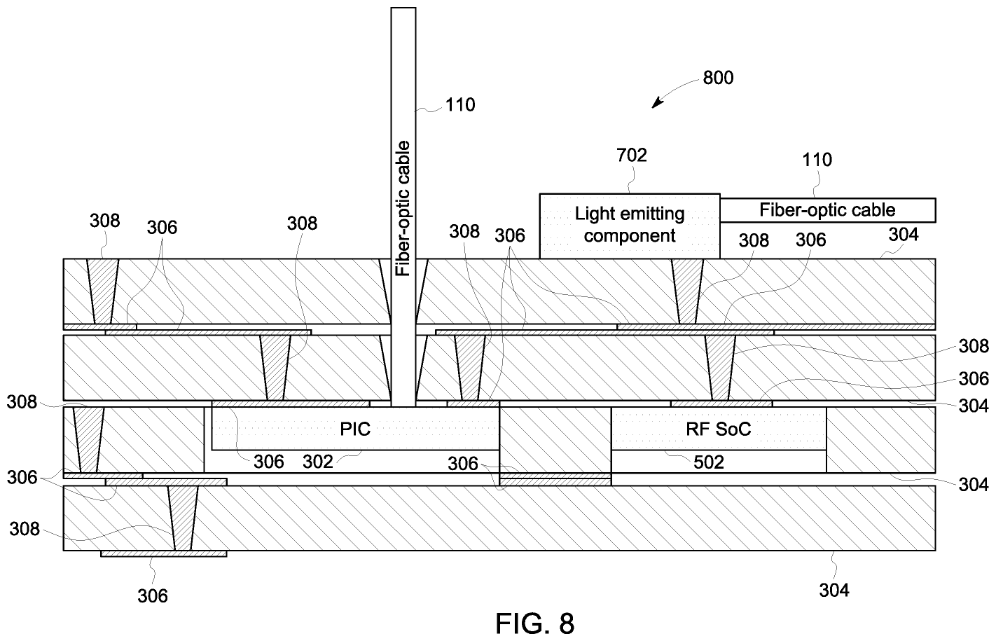

FIG. 8 depicts a cross-sectional view of an exemplary fiber-optic interface 800. Fiber-optic interface 700 includes PIC 302, fiber-optic interface substrate 304, conductive traces 306, vias 308, RF SoC 502, and light emitting component 702, which generally function as described with respect to FIGS. 3, 5, and 7. In the exemplary embodiment, light emitting component 702 is disposed on a surface of a fiber-optic interface substrate 304. While FIG. 8 depicts light emitting component 702 as disposed on a top, exterior surface of a fiber-optic interface substrate 304, in other embodiments, light emitting component 702 may be disposed on one or more different surfaces of one or more fiber-optic interface substrates 304, for example, via vertical coupling and/or edge coupling.

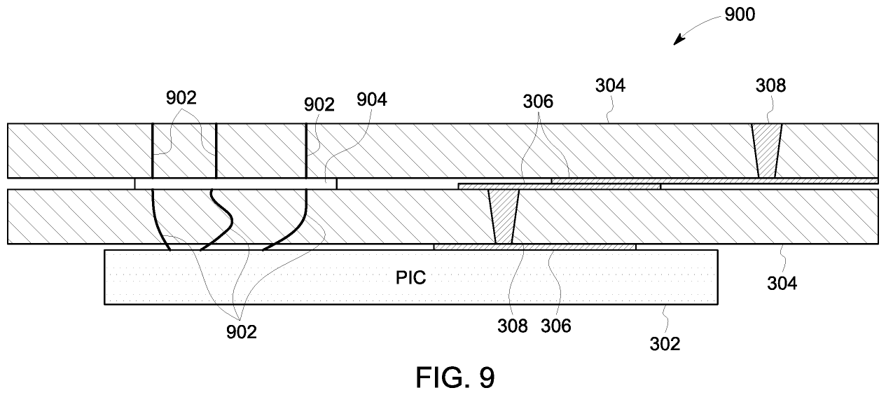

FIG. 9 depicts a cross-sectional view of an exemplary fiber-optic interface 900. Fiber-optic interface 900 includes PIC 302, fiber-optic interface substrate 304, conductive traces 306, and vias 308, which generally function as described with respect to FIG. 3. Fiber-optic interface 900 further includes optical waveguides 902 and an index matching adhesive 904. Optical waveguides 902 are configured to carry optical communication signals through, for example, fiber-optic interface substrates 304. Index matching adhesive 904 enables an optical communication signal carried by optical waveguides 902 to be transmitted across a gap between two fiber-optic interface substrates 304 while minimizing undesired degradation of the optical communication signal. In some embodiments, index matching adhesive 904 may additionally or alternatively be placed in other locations with respect to fiber-optic interface 900 to facilitate optical communication, for example, in voids between optical elements such as PIC 302.

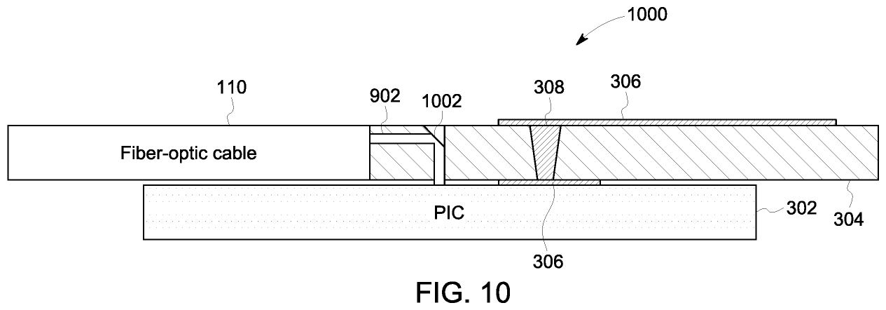

FIG. 10 depicts a cross-sectional view of an exemplary fiber-optic interface 1000. Fiber-optic interface 1000 includes PIC 302, fiber-optic interface substrate 304, conductive traces 306, vias 308, and optical waveguides 902 which generally function as described with respect to FIGS. 3 and 9. Fiber-optic interface 1000 further includes a mirror 1002. Mirror 1002 enables optical communication signals to be transmitted, for example, through a 90 degree bend in optical waveguide 902.

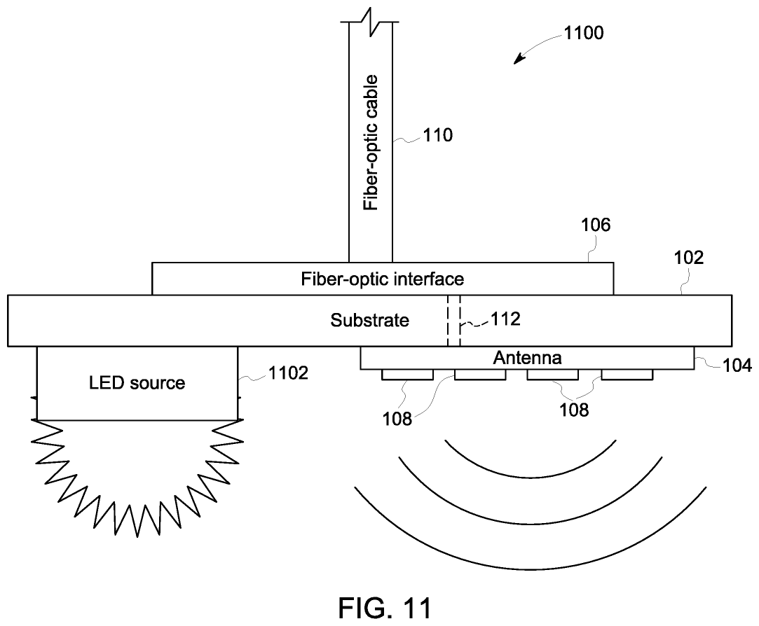

FIG. 11 depicts a schematic diagram of an exemplary wireless access point 1100. Wireless access point 1100 includes a substrate 102, an antenna structure 104, and a fiber-optic interface 106, which generally function as described with respect to FIG. 1. Wireless access point 1100 further includes an LED source 1102. LED source 1102 is configured to emit light. In some embodiments, LED source 1102 includes an LED and a drive circuit that provides power to the LED.

In an example embodiment, wireless access point 1100 serves both as a light fixture and as a 5G wireless access point. For example, each room of a building may include a wireless access point 1100. In the example embodiment, wireless access point 1100 is coupled to a general power supply to provide power to wireless access point 1100, and coupled to fiber-optic cable 110 to enable communication between wireless access point 1100 and a 5G router. Accordingly, wireless access point 1100 may be used to provide 5G connectivity to each room. In other example embodiments, wireless access point 1100 may be integrated into a display screen, a lighted exit and/or warning sign, and/or another appliance that may include a light source. In embodiments, where many wireless access points 1100 are integrated into a display screen, the many wireless access points 1100 form a patch antenna array structure. For example, each element of a row or column of lights in the display screen may include a wireless access point 1100 to form the array structure.

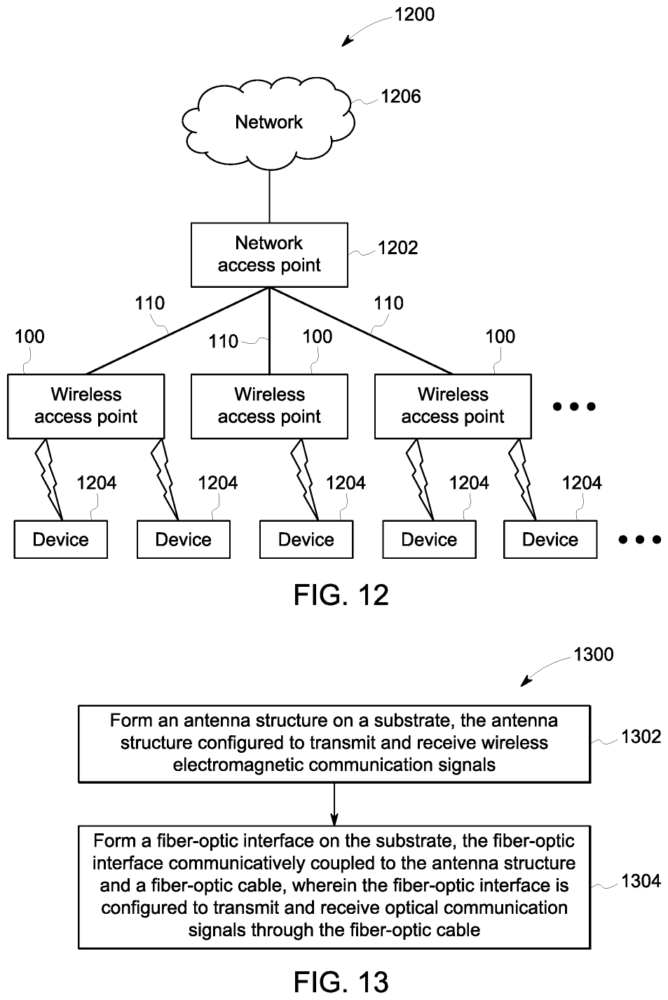

FIG. 12 depicts an exemplary wireless communication system 1200. Wireless communication system 1200 includes a network access point 1202, a plurality of devices 1204, a plurality of wireless access points 100, and a plurality of fiber-optic cables 110. Wireless access points 100 and fiber-optic cables 110 generally function as described with respect to FIG. 1.

Network access point 1202 is in communication with a communication network 1206 and is configured to facilitate communication between devices 1204 and other devices in communication with communication network 1206. For example, network access point 1202 may provide access to the Internet. Network access point 1202 is communicatively coupled to wireless access points 100 via fiber-optic cables 110, such that network access point 1202 and wireless access point 100 may exchange information using optical communication signals.

Devices 1204 are capable of wireless communication with wireless access points 100. For example, devices 1204 may be mobile telephones, tablets, computers, sensors, and/or other devices configured for wireless communication. Devices 1204 exchange information with wireless access points 100 using electromagnetic communications signals such as, for example, millimeter band signals. In some embodiments, devices 1204 and wireless access points exchange information using a wireless communication protocol such as, for example, a 5G cellular communication protocol.

In some embodiments, each wireless access point 100 may be disposed in, for example, a different room of a building, and may provide devices 1204 present in the same room with network access. Accordingly, each device 1204 receives network access even if wireless communication signals used between wireless access point 100 and devices 1204 cannot effectively or efficiently penetrate walls. In some exemplary embodiments, such as the embodiment illustrated in FIG. 3, wireless access points 100 may be integrated into appliances such as, for example, light fixtures.

In some embodiments, each wireless access point 100 may be disposed in a same room or outdoors, and the collective wireless access points 100 collectively increase a capacity of wireless communication system 1200 to communicate with many devices 1204 simultaneously. For example, wireless communication system 1200 may be disposed in a stadium, and a large number of wireless access points 100 may be integrated into light fixtures and display screens, and other appliances situated in and around the stadium. The large number of wireless access points 100 enable wireless communication system 1200 to effectively provide network access, for example, to a large number of mobile devices present during a sporting or music event held at the stadium. Some or all of the large number of wireless access points 100 may be turned on and off as needed for times of high or low data traffic. For example, in embodiments where many wireless access points 100 are placed in a stadium, at least some of the wireless access points may only be activated during stadium events.

FIG. 13 illustrates an exemplary method 1300 for manufacturing wireless access point 100 (shown in FIG. 1). Method 1300 includes forming 1302 an antenna structure on a substrate, the antenna structure configured to transmit and receive wireless electromagnetic communication signals. Method 1300 also includes forming 1304 a fiber-optic interface on the substrate, the fiber-optic interface communicatively coupled to the antenna structure and a fiber-optic cable, wherein the fiber-optic interface is configured to transmit and receive optical communication signals through the fiber-optic cable.

The embodiments described herein include a wireless access point that includes a substrate, an antenna structure disposed on the substrate and configured to transmit and receive a wireless electromagnetic communication signal, and a fiber-optic interface disposed on the substrate and communicatively coupled to the antenna structure and communicatively coupled to a fiber-optic cable. The fiber-optic interface is configured to transmit and receive an optical communication signal through the fiber-optic cable.

An exemplary technical effect of the methods, systems, and apparatus described herein includes at least one of: (a) improving wireless communication access by integrating wireless access points into various, distributed appliances; (b) enabling wireless access points to be easily integrated into various appliances by including transparent components in the wireless access point; (c) increasing the durability of an antenna structure for a wireless access point by using an antenna package that incorporates power overlay and/or embedded component technology; (d) increasing the efficiency of manufacture of an antenna structure for a wireless access point by using an antenna package that incorporates power overlay and/or embedded component technology; (e) improving a quality of service of a wireless access point by combining an RF electronics package with a photonic package; and (f) reducing loss in communication signals for 5G networks by using photonic links for long-distance transfer of data and millimeter band wireless signals for local transfer of data.

Exemplary embodiments of a wireless access point are described herein. The systems and methods of operating and manufacturing such systems and devices are not limited to the specific embodiments described herein, but rather, components of systems and/or steps of the methods may be utilized independently and separately from other components and/or steps described herein. For example, the methods may also be used in combination with other electronic systems, and are not limited to practice with only the electronic systems, and methods as described herein. Rather, the exemplary embodiment can be implemented and utilized in connection with many other electronic systems.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A wireless access point comprising:
a substrate;
an antenna structure disposed on said substrate and configured to transmit and receive wireless electromagnetic communication signals; and
a fiber-optic interface disposed on said substrate and communicatively coupled to said antenna structure and a fiber-optic cable, said fiber-optic interface configured to transmit and receive optical communication signals through the fiber-optic cable.

2. The wireless access point of claim 1, wherein said substrate comprises a transparent material.

3. The wireless access point of claim 1, wherein said substrate comprises a glass material.

4. The wireless access point of claim 1, wherein said substrate comprises a plurality of connected substrate layers.

5. The wireless access point of claim 1, wherein said antenna structure comprises a plurality of antennas.

6. The wireless access point of claim 5, wherein said plurality of antennas comprise patch antennas.

7. The wireless access point of claim 1, wherein said antenna structure comprises at least one conductive trace disposed on said substrate.

8. The wireless access point of claim 7, wherein said at least one conductive trace comprises indium tin oxide (ITO).

9. The wireless access point of claim 1, wherein said fiber-optic interface comprises at least one conductive trace disposed on said substrate.

10. The wireless access point of claim 9, wherein said at least one conductive trace comprises indium tin oxide (ITO).

11. The wireless access point of claim 1, wherein said fiber-optic interface comprises a photonic integrated circuit (PIC).

12. The wireless access point of claim 1, wherein the fiber-optic interface comprises a radio frequency system on a chip (RF SoC).

13. The wireless access point of claim 1, wherein one or more components of said wireless access point are embedded in said substrate.

14. The wireless access point of claim 1, further comprising an optical waveguide.

15. The wireless access point of claim 1, further comprising a light source.

16. The wireless access point of claim 15, wherein said light source comprises a light emitting diode (LED) and a LED drive circuit configured to supply power to said LED.

17. A wireless communication system comprising:
a network access point communicatively coupled to a communication network;
a plurality of fiber-optic cables communicatively coupled to the network access point; and
a plurality of wireless access points each comprising:
a substrate;
an antenna structure disposed on said substrate and configured to transmit and receive wireless electromagnetic communication signals; and
a fiber-optic interface disposed on said substrate and communicatively coupled to said antenna structure and at least one fiber-optic cable of said plurality of fiber-optic cables, said fiber-optic interface configured to transmit a first optical communication signal to said network access point and receive a second optical communication signal from said network access point through the fiber-optic cable.

18. The wireless communication system of claim 17, wherein said substrate of at least one wireless access point of said plurality of wireless access points comprises a transparent material.

19. The wireless communication system of claim 17, wherein said antenna structure of at least one wireless access point of said plurality of wireless access points comprises at least one conductive trace disposed on said substrate.

20. A method of manufacturing a wireless access point, said method comprising:
forming an antenna structure on a substrate, the antenna structure configured to transmit and receive wireless electromagnetic communication signals; and
forming a fiber-optic interface on the substrate, the fiber-optic interface communicatively coupled to the antenna structure and a fiber-optic cable, wherein the fiber-optic interface is configured to transmit and receive optical communication signals through the fiber-optic cable.
